(19) United States
(12) Patent Application Publication
(10) Pub. No.: US 2026/0090386 A1
(43) Pub. Date: Mar. 26, 2026

(54) SOIC NOVEL STRUCTURE FOR INNER DIE EDGE PROTECTION LAYER

(71) Applicant: Taiwan Semiconductor Manufacturing Co., Ltd., Hsinchu (TW)

(72) Inventors: Jen-Yuan CHANG, Hsinchu (TW); Yi-Chen LI, Hsinchu (TW)

(21) Appl. No.: 18/893,477

(22) Filed: Sep. 23, 2024

(51) Int. Cl. H01L 23/00; H01L 21/683; H01L 23/16; H01L 25/00; H01L 25/065

(52) U.S. Cl. CPC H10W 42/121; H10P 72/74; H10W 76/40; H10W 90/00; H10W 90/722

(57) ABSTRACT

A semiconductor structure includes a die structure. The die structure includes: a substrate; a first dielectric layer over the substrate; a first conductive structure within the first dielectric layer; a first edge protection layer on an edge surface of the first die structure; and a first insulating layer laterally adjacent to the first edge protection layer, the first edge protection layer between the first insulating layer and the edge surface of the first die structure.

### BACKGROUND

The semiconductor industry has experienced rapid growth due to ongoing improvements in the integration density of a variety of electrical components. To accommodate the miniaturized scale of the semiconductor device, various technologies and applications have been developed for the wafer-level packaging, involving greater numbers of different components with different functions. Improvement in integration density has resulted from iterative reduction of minimum feature size, which allows more components to be integrated into a given area.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired. In addition to smaller electronic components, improvements to the packaging of components seek to provide smaller packages that occupy less area than previous packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a flow diagram of a method of forming a semiconductor package structure, in accordance with some embodiments.

FIGS. 2-8 show a semiconductor structure in various stages of forming a semiconductor package structure, in accordance with some embodiments.

FIG. 9 shows a semiconductor package structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In the present disclosure, a semiconductor structure(s) and a method(s) of manufacturing a semiconductor structure are provided. Embodiments of the present disclosure are directed to a base or interconnection device die and to interconnection structures with additional dies connected therewith, such as a system on integrated chip (SoIC) packaging design and structure. The semiconductor structure includes a die structure surrounded, at least on a sidewall or edge surface of the die structure, by an edge protection layer, e.g., an oxynitride layer. The edge protection layer separates the edge surface of the die structure from gap filling dielectric materials such that such gap filling dielectric material will not extend into a gap or crack, if any, in the edge surface of the die structure. Other features and processes may also be included. In some embodiments, the method of manufacturing the semiconductor structure includes forming an edge protection layer including an oxynitride layer to surround an edge surface of a die structure in an assembly process. As a result, among others, development of gap fill dielectric cracks can be reduced or prevented. The overall strength of the semiconductor structure can be increased or improved.

Examples of the type of packages for semiconductors include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices (e.g., 3DIC, SoC, SoIC) are prepared by placing chips over chips on a semiconductor wafer level. These three-dimensional devices provide improved integration density and other advantages, such as faster speeds and higher bandwidth due to the decreased length of interconnects between the stacked chips. However, there are many challenges related to three-dimensional devices.

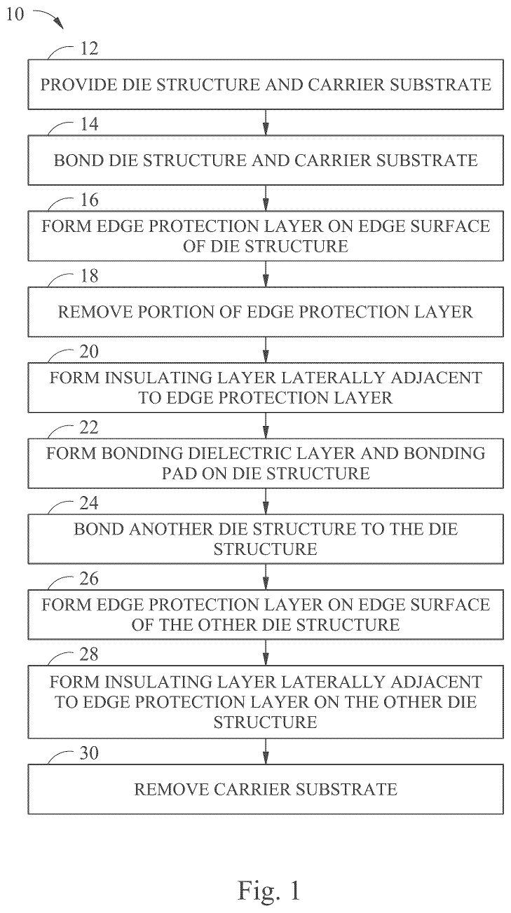

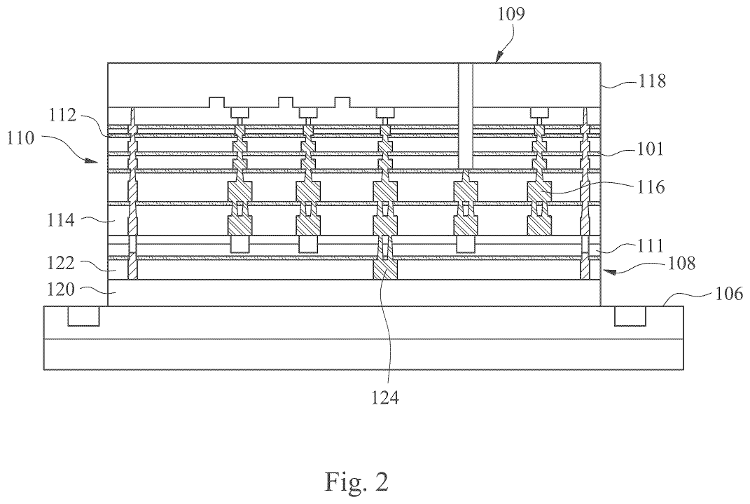

FIG. 1 is a flow diagram of a method 10 of manufacturing a semiconductor structure in accordance with some embodiments of the present disclosure. FIG. 1 is an embodiment of the method 10 of manufacturing a semiconductor structure. The method 10 includes a number of operations. In operation 12, a carrier substrate 106 and a first die structure 101 are provided as shown in FIG. 2. The carrier substrate 106 is configured to temporarily support a substrate or device thereon. The carrier substrate 106 is a blank glass, ceramic, silicon or other suitable carrier substrate. The first die structure 101 can be any single piece of semiconductor die or a stack of multiple semiconductor dies arranged vertically and/or laterally with respect to one another.

Referring to FIG. 2, in some example implementations, the semiconductor die 101 includes a first semiconductor substrate (or base semiconductor substrate) 108 and various back-end-of line BEOL structures 110. In some embodiments, the first semiconductor substrate 108 may include an elementary semiconductor such as silicon or germanium and/or a compound semiconductor such as silicon germanium, silicon carbide, gallium arsenic, indium arsenide, gallium nitride or indium phosphide. In some embodiments, the first semiconductor substrate 108 may be a semiconductor-on-insulator (SOI) substrate. In various embodiments, the first semiconductor substrate 108 may take the form of a planar substrate, a substrate with multiple fins, nanowires, or other forms known to people having ordinary skill in the art. Depending on the requirements of design, the first semiconductor substrate 108 may be a P-type substrate or an N-type substrate and may have doped regions, e.g., P-well or N-well, therein. The doped regions may be configured for an N-type device or a P-type device.

In some embodiments, the first semiconductor substrate 108 includes isolation structures, e.g., shallow trench isolations STI, defining at least one active area, and a first device layer may be disposed on/in the active area. The first device layer 111 may include a variety of devices. In some embodiments, the variety of devices may include active components, passive components, or a combination thereof. In some embodiments, the first semiconductor substrate 108 may include circuit components that form a memory array or other memory structure. In some embodiments, the first semiconductor substrate 108 may include circuit components that provide non-memory functionality, such as communication, logic functions, processing, or the like. In some embodiments, the devices may include integrated circuits devices. The devices may be, for example, transistors, capacitors, resistors, diodes, photodiodes, fuse devices, or other similar devices. In some embodiments, the first device layer includes gate electrodes, source or drain regions, spacers, and the like.

The BEOL structures 110 includes layers stacked on the substrate 108 till a surface 109 of the die 100 opposite to the substrate 108. The BEOL structures 110 may include an inter-layer dielectric (ILD) 112, one or more inter-metal dielectric (IMD) layers 114, various metal features 116, and a passivation layer 118. In some embodiments, the ILD 112 may be formed of a dielectric material such as silicon oxide (SiO2) silicon nitride (SiN or Si3N4), silicon carbide (SiC), or the like, and may be deposited by any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like.

The IMD layers 114 may include an extra low-k (ELK) dielectric material having a dielectric constant (k) less than about 2.6, such as from 2.5 to 2.2. In some embodiments, ELK dielectric materials include carbon-doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials may include porous versions of existing dielectric material, such as porous hydrogen silsesquioxane (HSQ), porous methyl silsesquioxane (MSQ), porous polyarylether (PAE), porous SiLK, or porous SiO2. The IMD layers 114 may be formed by any suitable deposition process. In some embodiments, the IMD layers 114 may be deposited by a PECVD process or by a spin coating process.

The metal or conductive features 116 may include wires, lines and via structures. The metal features 116 may be formed of any suitable electrically conductive material, such as tungsten (W), copper (Cu), a copper alloy, aluminum (Al), an aluminum alloy, silver, gold, combinations thereof, or the like. Other suitable electrically conductive materials, e.g., conductive nitride compounds, are also possible and within the scope of disclosure.

In operation 14, with reference also to FIG. 2, the first die structure 101 is bonded over the carrier substrate 106. The first die structure 101 is bonded with the carrier substrate 106 by a bonding film, e.g., a polymeric film 120, disposed between a bonding dielectric layer 122, e.g., a RDL layer, of the first die structure 101 and the carrier substrate 106. The bonding dielectric layer 122 may also include bonding pads 124 formed therein, which enables electrical or thermal coupling to the bonding film 120. The bonding film 120 is a release film, die attach film (DAF), adhesive or other materials that can be used for bonding dies.

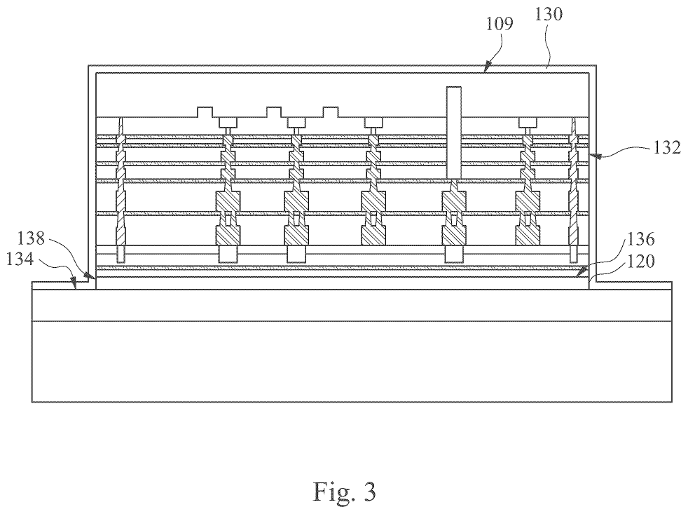

In operation 16, an edge protection layer, e.g., an oxynitride layer 130, is disposed over the carrier substrate 106 and the first die structure 101 as shown in FIG. 3. The oxynitride layer 130 is disposed by deposition, chemical vapor deposition (CVD) or any other suitable procedures. In some implementations, the oxynitride layer 130 is disposed to cover the upper surface 109 and edge or sidewall surfaces 132 of the first die structure 101. The oxynitride layer 130 is in contact with the upper surface 109 and the edge surfaces 132 of the first die structure 101. In some implementations, the oxynitride layer 130 is also on edge surfaces of the bonding film 120 and on surface 134 of the carrier substrate 106 that faces the first die structure 101. In some implementations, the bonding film 120 may extend beyond the first die structure 101 (not shown in FIG. 3), and the oxynitride layer 130 may be disposed on an upper surface 136 of the bonding film 120 that faces the first die structure 101.

In some implementations, the oxynitride layer 130 includes more than a first percentage of 5% of oxygen content by, e.g., weight. For example, the oxynitride layer 130 includes silicon oxynitride. In some embodiments, a thickness of the oxynitride layer 130 is greater than 10 A. In some implementations, the thickness of the oxynitride layer 130 is in a range from about 10 A to about 80 A.

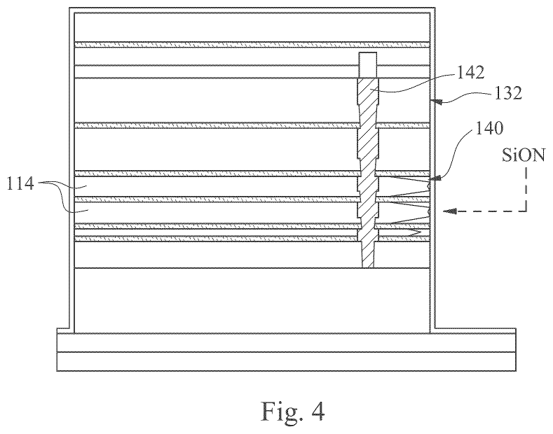

In some implementations, as shown in FIG. 4, the oxynitride layer 130 extends into gaps or cracks 140 in the edge surfaces 132 of the first die structure 101. The gaps or cracks 140 may come from unexpected mechanical forces or chemical reactions in the procedures of handling the first die structure 101 before or during the operation 14 where the first die structure 101 is bonded to the carrier substrate 106. For example, the gaps or cracks 140 may form in or vertically adjacent to the inter-metal dielectric (IMD) layers 114 on the edge surfaces 132 of the first die structure 101. For example, the gaps or cracks 140 may form vertically between the inter-metal dielectric (IMD) layers 114 and another dielectric layer, e.g., an etch stop layer. The gaps or cracks 140 may be formed through unexpected physical forces or chemical reactions. For example, the plasma dicing dry etch process may selectively remove more dielectric materials from the edge surface 132 of the die structure, resulting in gaps or cracks 140 because low K dielectric materials normally have higher etch rate compared to other materials, like metal materials or other dielectric materials like silicon oxide. For another example, picking, placing, or baking the first die structure 101 all may cause micro cracks on the edge surfaces 132, resulting in gaps or cracks 140.

The gaps or cracks 140 may be adjacent to a metal structure in the first die structure 101. For example, the gaps or cracks 140 on the edge surfaces 132 may be adjacent to an inner die seal ring structure 142 of the first die structure 101. The oxynitride layer 130 can prevent gap filling materials surrounding the first die structure 101 (further described herein later), e.g., SiO₂, from entering the gaps or cracks 140 so that the metal materials, e.g., copper Cu, of the adjacent metal structure, e.g., the inner die seal ring structure 142, will not diffuse into the filling material SiO₂, which improves the reliability of the semiconductor device. Further, if SiO₂ fills into the gaps or cracks 140, the SiO2 will grow unevenly, which may cause stress to be accumulated. The oxynitride layer 130 can prevent or reduce such risks of structural defects by precenting the surrounding SiO₂ from extending into the gaps or cracks 140, if any.

The oxynitride layer 130 can be formed to cover the first die structure 101 using a reactive gas on a surface of the first die structure 101 using any kind of processes. For example, the reactive gas may be N₂, NH₄, C₂H₄, or other suitable reactive gas treatments. A multi-chip process, e.g., using a furnace tube, or a monolithic process, e.g., using a heater chamber, may be used to effectuate the reactive gas treatment. Other suitable processes may also be used and included in the scope of the disclosure.

In some implementations, the edge protection layer 130 may be a material different from oxynitride. For example, the edge protection layer 130 may be a nitride containing carbon and compounds such as SiOCN. A SiOCN layer 130 may be formed using a reactive gas treatment on the surfaces of the die structure 101 using any kind of processes. For example, the reactive gas may be NH₄ and C₂H₄ together. Other dielectric materials are also possible for the edge protection layer 130, which are included in the scope of the disclosure.

In some implementations, the edge protection layer 130 can include multiple layers on one another. The multiple layers may have different materials, e.g., including oxynitride and nitride, and may include different thickness values.

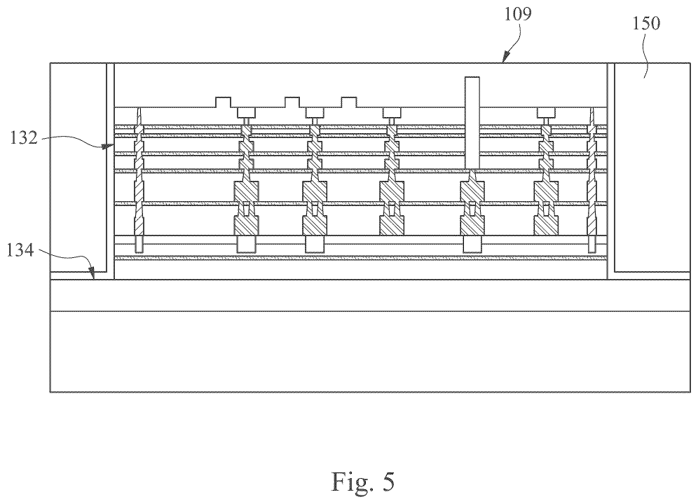

In operation 18, referring also to FIG. 5, portions of the edge protection layer 130 are removed, e.g., from upper surface 109 of the die structure 101. As shown in FIG. 5, in some implementations, portions of the edge protection layer 130 on the upper surface 109 of the first die structure 101 has been removed. The edge protection layer 130 remains on the edge surface 132 of the first die structure 101, on the edge surface 138 of the bonding film 120, and on the upper surface 134 of the carrier substrate 106 that faces the die structure 101. The edge protection layer 130 remains within the gaps or cracks 140 (FIG. 4). Other portions of the edge protection layer 130, e.g., the portion of it on the surface 134 of the carrier substrate 106, may also be removed, as applicable in various design scenarios. In some implementations, measures are taken to maintain at least a portion of the edge protection layer 130 to remain on the edge surface 132 of the first die structure 101. After the operation 18, the thickness of the remaining portion of the edge protection layer 130 on the edge surface 132 of the die structure 101 may be in a range from 1 A to about 10 A. In some implementations, in a case that the edge protection layer 130 is SiON, the remaining thickness of the edge protection layer 130 on the edge surface 132 may be in a range from 1 A to about 5 A. In a case that the edge protection layer 130 is a dielectric material other than SiON, the remaining thickness of the edge protection layer 130 on the edge surface 132 may be different, and in some implementations may be 50% of the thickness of SiON as the edge protection layer 130.

The removal of the portions of the edge protection layer 130 may be effectuated through grinding and/or chemical machinal polishing (CMP) or other suitable procedures, which are all included in the scope of the disclosure.

With the edge protection layer 130 remains on the edge surface 132 of the first die structure 101, in operation 20, with reference also to FIG. 5, an insulating layer 150 is formed on the carrier substrate 106 and surrounding or laterally adjacent to the edge protection layer 130 and the first die structure 101. For example, the insulating layer 150 is formed on a portion of the surface 134 of carrier substrate 106 that is not occupied or overlapped by the first die structure 101 such that the insulating layer 150 fills a “gap” left out by the first die structure 101. In some implementations, the insulating layer 150 is disposed over the carrier substrate 106, the first die structure 101, and the edge protection layer 130, and then a portion of the insulating layer 150 is removed, e.g., to expose the upper surface 109 of the first die structure 101. A grinding and/or CMP procedure may be conducted to effectuate the removal of portions of the insulating layer 150. The insulating layer 150 may include oxide, silicon oxide or other dielectric materials. The insulating layer 150 may include a dielectric material that has gap filling properties or characteristics. In some embodiments, a second percentage of oxygen content, e.g., in weight, of the insulating layer 150 is greater than the first percentage of oxygen content of the edge protection layer 130.

In some implementations, the operation 18 is conducted as part of the operation 20. For example, the insulating layer 150 is disposed while the edge protection layer 130 remains on upper surface 109 of the first die structure 101. Portions of the edge protection layer 130 and the insulating layer 150 are removed together to expose the upper surface 109 of the first die structure 101, as shown in FIG. 5. The removal may be effectuated through one or more of etching, planarization, chemical mechanical polishing (CMP) or any other suitable procedures.

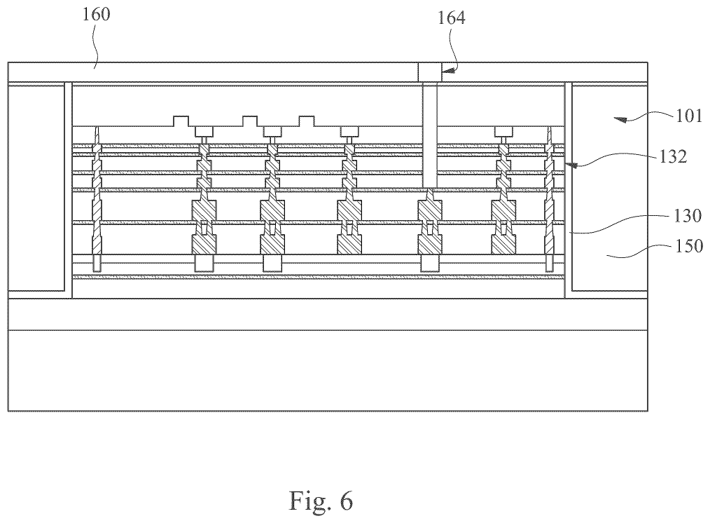

In operation 22, with reference also to FIG. 6, a bonding dielectric layer 160 and a bonding pad 162 are formed over the first die structure 101, the edge protection layer 130, and the insulating layer 150. The bonding dielectric layer 160 may be formed by disposing a bonding dielectric material over the first die structure 101, the edge protection layer 130, and the insulating layer 160 by deposition, CVD or any other suitable procedures.

The bonding pad 162 may be formed in a via or through hole in the bonding dielectric layer 160. For example, portions of the bonding dielectric material may be removed by etching or any other suitable procedures, thereby forming an opening 164 extending through the bonding dielectric layer 160. The bonding pad 162 is formed by disposing conductive material into the opening 164 by electroplating, sputtering, deposition or any other suitable procedures. The bonding dielectric layer 160 and the bonding pad 162 may have similar configurations as the bonding dielectric layer 122 and the bonding pad 124 (FIG. 2).

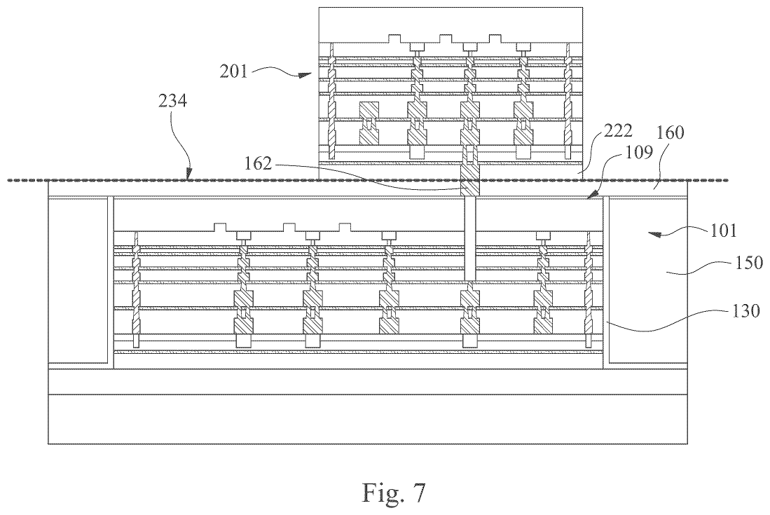

In operation 24, with reference also to FIG. 7, a second die structure 201 is bonded to the first die structure 101. For example, the second die structure 201 is provided on the bonding dielectric layer 160, and bonded to the first die structure 101 through a bonding dielectric layer 222 formed on the second die structure 201. For example, a bonding pad 224 formed in the bonding dielectric layer 222 of the second die structure 201 is bonded to the bonding pad 162, and the bonding dielectric layer 222 is bonded to the bonding dielectric layer 160. The second die structure 201 may be bonded with the first die structure 101 by hybrid bonding or any other suitable bonding procedures. In some embodiments, a portion of the bonding dielectric 160 is exposed after the bonding of the first die structure 101 with the second first die structure 201, and the exposed portion includes an surface 234 of the bonding dielectric layer 160 that faces the second die structure 201.

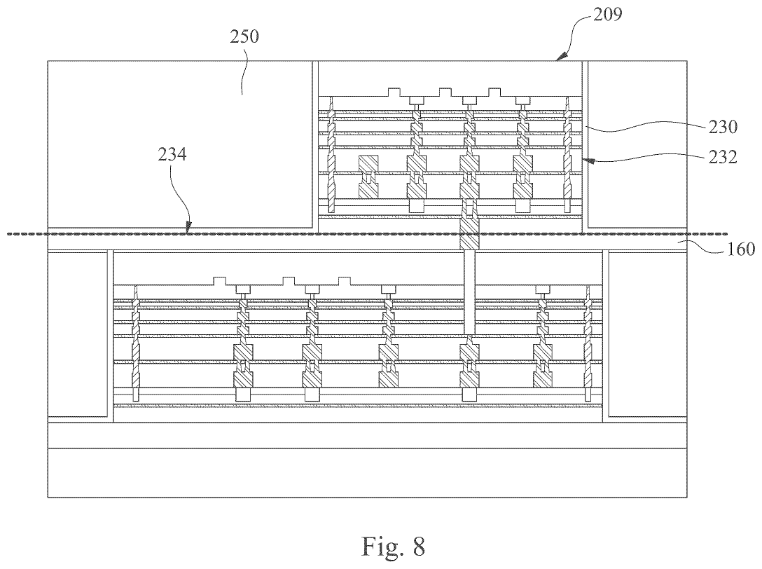

In operation 26, with reference also to FIG. 8, after the bonding of the first die structure 101 with the second die structure 201, an edge protection layer 230 is disposed on edge surfaces 232 of the second die structure 201 and on surface 234 of the bonding dielectric layer 160 that is exposed from the second die structure 201. The material composition and forming procedure of the edge protection layer 230 on the second die structure 201 may be THE same as or different from those of the edge protection layer 130 on the first die structure 101. In some implementations, some portions of the edge protection layer 230 is removed so that an upper surface 209 of the second die structure 201 is exposed. Similar to those shown in FIG. 4, the edge protection layer 230 extends into gaps or cracks in the edge surface 232 of the second die structure 201 (not shown in FIG. 8 for simplicity).

In operation 28, after the edge protection layer 230 is formed on the edge surfaces 232 of the second die structure 201, an insulating layer 250 is formed on the bonding dielectric layer 160 and surrounding or laterally adjacent to the second die structure 201. For example, the insulating layer 250 is formed on a portion of the surface 234 of bonding dielectric layer 160 that is not occupied or overlapped by the second die structure 201 such that the insulating layer 250 fills a “gap” left out by the second die structure 201. In some implementations, the insulating layer 250 is disposed over the bonding dielectric layer 160, the second die structure 201, and the edge protection layer 230, and then a portion of the insulating layer 250 is removed, e.g., to expose the upper surface 209 of the second die structure 101. A grinding and/or CMP procedure may be conducted to effectuate the removal of portions of the insulating layer 250. The insulating layer 250 may include oxide, silicon oxide or other dielectric materials. In some embodiments, an oxygen content of the insulating layer 250, e.g., in weight percentage, is greater than the oxygen content of the edge protection layer 230.

In some implementations, in a case that there is no other die structure arranged on the second die structure 201, one or more of the insulating layer 250 or the edge protection layer 230 may not be removed from the surface 209 of the second die structure 201.

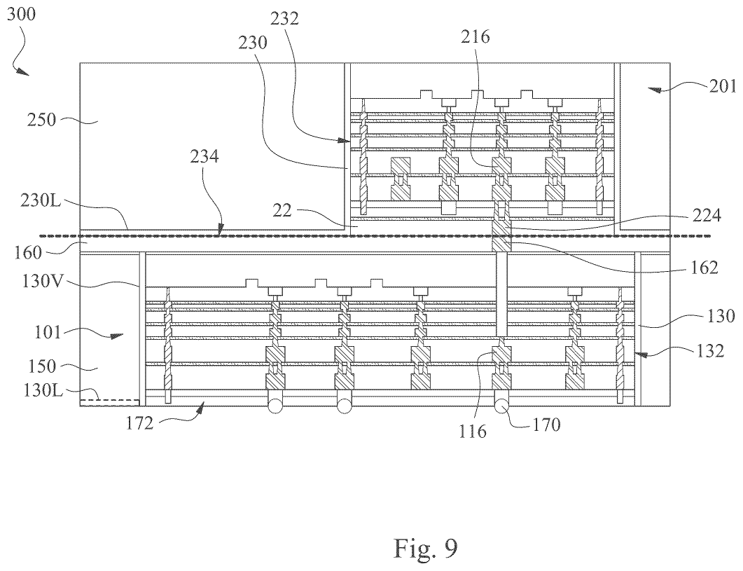

In operation 30, with reference also to FIG. 9, the carrier substrate 106 is removed. The carrier substrate 106 is de-bonded from the first die structure 101. For example, the carrier substrate 106 is detached from the first die structure 101 by irradiating the polymeric film 107 with an electromagnetic radiation such as UV light.

After the detachment of the carrier substrate 106, the bonding film 120, portions of the edge protection layer 130, and portions of the insulating layer 150 may be removed to expose the conductive pad 124 in the bonding dielectric layer 122. The bonding film 120, portions of the edge protection layer 130, and portions of the insulating layer 150 can be removed by planarization, etching, CMP or any other suitable procedures. In some implementations, the bonding dielectric layer 122, the edge protection layer 130 and the insulating layer 150 forms a same level of the surface 172.

In some embodiments, a conductive bump or ball 170 is formed on the conductive pad 124 in the bonding dielectric layer 122 as shown in FIG. 9. The conductive bump or ball 170 is disposed by electroplating, solder pasting, ball placement or any other suitable procedures.

As shown in FIG. 9, a semiconductor package structure 300 in accordance with some embodiments of the present disclosure includes a first die structure or semiconductor structure 101 and a second die structure or semiconductor structure 201 stacked on the first die structure 101. The second semiconductor structure 201 is bonded with the first semiconductor structure 101. In some embodiments, the semiconductor package structure 300 is system on integrated circuit (SoIC) structure, chip on wafer on substrate (CoWoS) structure, integrated fan out (InFO) structure, other 3D package structures, or other package structures that involving multiple semiconductor dies assembled within the same package. The second semiconductor structure 201 is electrically connected to the first semiconductor structure 101 through, e.g., bonding pads 162, 224.

The bonding dielectric layer 222 of the second semiconductor structure 201 is bonded with the bonding dielectric layer 160 formed on the first semiconductor structure 300, and the bonding pad 224 of the second semiconductor structure 201 is bonded with the bonding pad 162 in the bonding dielectric layer 160. Each of the bonding pad 162 and the bonding pad 224 extends through the relevant dielectric layer 160, 222, and is coupled to a conductive feature 116, 216 of a semiconductor structure 101, 201, respectively.

An edge protection layer 130, 230 is disposed on the edge surface 132, 232 of each of the semiconductor structure 101, 201. The edge protection layer 130, 230 is positioned between and separating gap filling insulting layer 150, 250 from the edge surface 132, 232 of the corresponding semiconductor structure 101, 201. The edge protection layer 130, 230 may extend into gaps or cracks 140 in the edge surfaces 132, 232 of the corresponding semiconductor structure 101, 201. The edge protection layer 230 may extend on the surface 234 of the bonding dielectric layer 160 between the first semiconductor structure 101 and the second semiconductor structure 201. The edge protection layer 230 may be positioned vertically between the insulating layer 150 and the insulating layer 250 in a portion 230L of the edge protection layer 230 that extends on the surface 234 of the bonding dielectric layer 160.

The edge protection layer 130 may be exposed on the surface 172 of the first semiconductor structure 101 on which the conductive bump or ball 170 is formed on.

In some implementations, in a case the bonding film 120 (FIG. 3) extends beyond the first die structure 101 (not shown in FIG. 3), and the edge protection layer 130 is disposed on an upper surface 136 of the bonding film 120 that faces the first die structure 101, the edge protection layer 130 may include a portion 130L that extends from a portion 130V of the edge protection layer 130 and along the surface 172. For example, the portion 130L of the edge protection layer 130 is not totally removed when de-bonding the bonding film 120. The portion 130L of the edge protection layer 130 is positioned vertically between the insulating layer 150 and the surface 172.

The portion 130V, 230V of the edge protection layer 130, 230 prevents the insulating layer 150, 250 from extending into the gaps of cracks in the edge surfaces 132, 232 of the corresponding semiconductor structure 101, 201. The portion 130V, 230V of the edge protection layer 130, 230 also prevents metal materials of the conductive features in the semiconductor structure 101, 201 from diffusing into the insulting layer 150, 250. As such, among others, the edge protection layer 130, 230 improves the mechanical reliability and electrical reliability of the package 300.

In some implementations, one or more of the edge protection layer 130, 230 is a multi-layer structure and may include multiple layers of different materials. For example, one or more of the edge protection layers 130, 230 may include a first SiON layer, a second SiON layer and a nitride layer sandwiched between the first SiON layer and the second SiON layer.

In some embodiments, each of the die structure or semiconductor structure 101, 201 is a die, a chip or a package. In some embodiments, the die structure 101, 201 is a logic die, a central processing unit (CPU) die, a micro control unit (MCU) die, an input-output (IO) die, an application processor (AP) die, or the like. The die structure 101, 201 may include a substrate, a semiconductor device formed in the substrate, a die pad, a passivation layer, a first dielectric layer, a interconnect structure, a conductive pad, and/or a conductive bump.

In an embodiment, a semiconductor structure includes a first die structure. The first die structure includes: a substrate; a first dielectric layer over the substrate; a first conductive structure within the first dielectric layer; a first edge protection layer on an edge surface of the first die structure; and a first insulating layer laterally adjacent to the first edge protection layer, the first edge protection layer between the first insulating layer and the edge surface of the first die structure.

In an embodiment, a semiconductor structure includes: a first die structure, a bonding dielectric layer on the first die structure, a second die structure on the bonding dielectric layer, a first edge protection layer on an edge surface of the first die structure, a first insulating layer laterally adjacent to the first edge protection layer, which is between the first insulating layer and the edge surface of the first die structure, a second edge protection layer on an edge surface of the second die structure, and a second insulating layer on the bonding dielectric layer and laterally adjacent to the second edge protection layer, the second edge protection layer between the second insulating layer and the edge surface of the second die structure.

In an embodiment, a method includes: bonding a die structure to a base; performing an N2 treatment to form an edge protection layer on an edge surface of the die structure; and forming an insulating layer laterally adjacent to the edge protection layer, the edge protection layer between the insulating layer and the edge surface of the die structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a first die structure, the first die structure including:
a substrate;
a first dielectric layer over the substrate;
a first conductive structure within the first dielectric layer;
a first edge protection layer on an edge surface of the first die structure; and
a first insulating layer laterally adjacent to the first edge protection layer, the first edge protection layer between the first insulating layer and the edge surface of the first die structure.

2. The semiconductor structure of claim 1, wherein the first edge protection layer includes a different dielectric material from the first insulating layer.

3. The semiconductor structure of claim 1, wherein the first insulating layer comprises SiO₂ and the first edge protection layer comprises an oxynitride.

4. The semiconductor structure of claim 1, wherein the first insulating layer comprises SiO₂ and the first edge protection layer comprises an oxy-carbon-nitride.

5. The semiconductor structure of claim 1, wherein the first edge protection layer includes a first percentage of oxygen content and the first insulating layer includes a second percentage of oxygen content, the first percentage smaller than the second percentage.

6. The semiconductor structure of claim 1, wherein the first edge protection layer extends into a gap in the edge surface of the first die structure.

7. The semiconductor structure of claim 1, wherein the gap is in the first dielectric layer or vertically adjacent to the first dielectric layer.

8. The semiconductor structure of claim 1, comprising a base layer, wherein the first die structure, the first insulating layer and the first edge protection layer are on the base layer.

9. The semiconductor structure of claim 8, wherein a portion of the first edge protection layer is vertically between base layer and the first insulating layer.

10. The semiconductor structure of claim 8, comprising a conductive pad in the base layer, wherein the conductive pad is coupled to the first conductive structure.

11. The semiconductor structure of claim 10, wherein the conductive pad extends through the base layer.

12. The semiconductor structure of claim 1, wherein the first die structure includes a bonding dielectric layer, the bonding dielectric layer and the first edge protecting layer on a same level of a surface of the semiconductor structure.

13. The semiconductor structure of claim 12, wherein the first insulating layer is on the same level of the surface of the semiconductor structure.

14. The semiconductor structure of claim 12, wherein a portion of the first edge protection layer is vertically between the first insulating layer and the surface of the semiconductor structure.

15. The semiconductor structure of claim 12, comprising a bonding pad in the bonding dielectric layer.

16. The semiconductor structure of claim 15, comprising a conductive bump or conductive ball on the bonding pad.

17. The semiconductor structure of claim 1, comprising:
a bonding dielectric layer on the first die structure;
a second die structure on the bonding dielectric layer;
a second edge protection layer on an edge surface of the second die structure; and
a second insulating layer laterally adjacent to the second edge protection layer, the second edge protection layer between the second insulating layer and the edge surface of the second die structure,
wherein the second edge protection layer is vertically between the second insulting layer and the bonding dielectric layer.

18. A semiconductor structure, comprising:
a first die structure;
a bonding dielectric layer on the first die structure;
a second die structure on the bonding dielectric layer;
a first edge protection layer on an edge surface of the first die structure;
a first insulating layer laterally adjacent to the first edge protection layer, the first edge protection layer between the first insulating layer and the edge surface of the first die structure;
a second edge protection layer on an edge surface of the second die structure; and
a second insulating layer on the bonding dielectric layer and laterally adjacent to the second edge protection layer, the second edge protection layer between the second insulating layer and the edge surface of the second die structure.

19. The semiconductor structure of claim 18, wherein the second edge protection layer is on the bonding dielectric layer and vertically between the second insulating layer and the bonding dielectric layer.

20. A method comprising:
bonding a die structure to a base;
performing an N₂ treatment to form an edge protection layer on an edge surface of the die structure; and
forming an insulating layer laterally adjacent to the edge protection layer, the edge protection layer between the insulating layer and the edge surface of the die structure.
